(19) United States
(12) Patent Application Publication
(10) Pub. No.: US 2009/0190467 A1
(43) Pub. Date: Jul. 30, 2009

(54) SYSTEM AND METHOD FOR MANAGING FAULT IN A MULTI PROTOCOL LABEL SWITCHING SYSTEM

(75) Inventor: Moshiur RAHMAN, Marlboro, NJ (US)

Correspondence Address: AT & T LEGAL DEPARTMENT - NDQ, ATTN: PATENT DOCKETING, ONE AT & T WAY, ROOM 2A-207, BEDMINSTER, NJ, 07921, US

(73) Assignee: AT&T Labs, Inc., Austin, TX (US)

(21) Appl. No.: 12/019,812

(22) Filed: Jan. 25, 2008

(51) Int. Cl. G01R 31/08

(52) U.S. Cl. 370/216; 370/242

(57) ABSTRACT

A system, method and computer readable media for detecting and managing fault within a network using the network's label distribution protocol transactions. Initially, the system will monitor and analyze all transactions within the network to determine if the network has degraded at or between any nodes in the system. The system can then recognize if there is any failure and determine if the network has degraded past a threshold value that is needed for proper operation. If the network has a failure that is beyond this threshold, it will notify a fault management system and subsequently a ticketing system to notify the user that a failure within the system has occurred.

### BACKGROUND OF THE INVENTION

1. Field of the Invention

This invention relates to multi protocol label switching networks. More specifically, it relates to detecting faults in these networks.

2. Introduction

Currently, keeping networks functioning and keeping customers satisfied with the quality of network services is difficult and improvements are needed to ensure reliability. Networks operating on the Multi Protocol Label Switching (MPLS) standards are developing as a preferred protocol. MPLS networks operate by having a router append a MPLS header onto packets that are to be transferred. These MPLS headers contain at least one label that is used within the MPLS network to transfer the packet rather than having to consult a routing table as necessitated by other protocols. The routers that transfer packets within the MPLS network are called Label Switched Routers (LSR) which use the labels in the MPLS header to properly route the packet. Routers at the ingress and egress points of the network are called Label Edge Routers (LER) and LERs push or pop the MPLS headers onto or off of the packets respectively.

MPLS networks will use a Label Distribution Protocol (LDP) in order to set up a Label Switched Path (LSP) between two or more LSRs. LSRs normally exchange information about labels and accessibility with enough frequency to recognize the overall ability of the network to carry packets. Therefore, by recognizing the entire availability of the network, the LSRs are able to utilize the LDP to create the best LSP to transfer the packets. The packets will then follow the LSP through the designated LSRs. LSRs use LDP protocol to establish LSPs through a network by mapping network layer routing information directly to data link layer switched paths. One byproduct of the LDP being implemented is the knowledge of the LSRs that a certain path is not available, this knowledge coming from the communication between LSRs. Currently, the LSRs choose the best path available without considering why the chosen path is best. This lack of consideration needs to be remedied so that if there is a problem in the network, it can be fixed prior to a degradation of service or customer complaint.

### SUMMARY OF THE INVENTION

Additional features and advantages of the invention will be set forth in the description which follows, and in part will be obvious from the description, or may be learned by practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth herein.

Disclosed are systems, methods and computer readable media for detecting and managing fault within a network by monitoring transaction within the network's label distribution protocol transactions. The monitor will also analyze those transactions to determine if there have been any failures or shortcomings in the network. The system recognizes the failures that do occur in the label distribution protocol transactions and checks to see if those failures are within an acceptable range that allows the network to continue to operate properly. If the network is not operating within acceptable limits, then the system will notify a fault management system and subsequent to that notification, will produce a ticket that allows the user to be notified that the network is outside of operable limits. This will allow the user to be proactive and take precautions to maintain an acceptable level of functionality in the network.

Thus the principles of this system can better utilize the information that is available in a network protocol. Further, the system will allow better user to better utilize quality control to improve customer satisfaction due to the increase in reliability of the system.

### BRIEF DESCRIPTION OF THE DRAWINGS

In order to describe the manner in which the above-recited and other advantages and features of the invention can be obtained, a more particular description of the invention briefly described above will be rendered by reference to specific embodiments thereof which are illustrated in the appended drawings. Understanding that these drawings depict only typical embodiments of the invention and are not therefore to be considered to be limiting of its scope, the invention will be described and explained with additional specificity and detail through the use of the accompanying drawings in which:

FIG. 1 illustrates a basic system or computing device for use with the present system;

FIG. 2 illustrates a basic MPLS system; and

FIG. 3 illustrates a method embodiment of the present application.

### DETAILED DESCRIPTION OF THE INVENTION

Various embodiments of the invention are discussed in detail below. While specific implementations are discussed, it should be understood that this is done for illustration purposes only. A person skilled in the relevant art will recognize that other components and configurations can be used without parting from the spirit and scope of the invention.

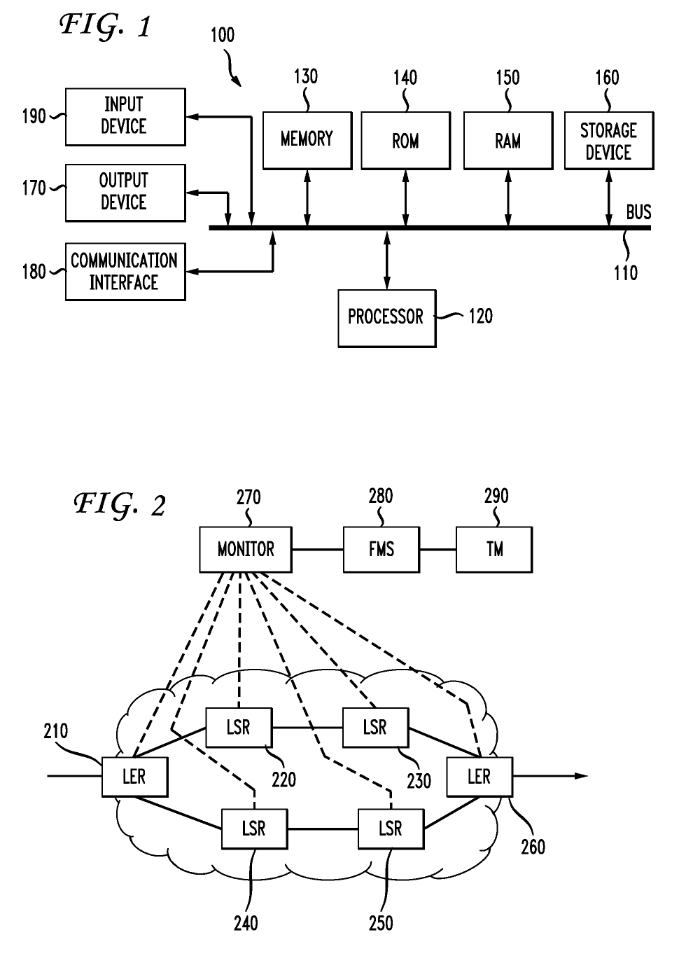

With reference to FIG. 1, an exemplary system for implementing the invention includes a general-purpose computing device 100, including a processing unit (CPU) 120 and a system bus 110 that couples various system components including the system memory such as read only memory (ROM) 140 and random access memory (RAM) 150 to the processing unit 120. Other system memory 130 may be available for use as well. It can be appreciated that the invention can operate on a computing device with more than one CPU 120 or on a group or cluster of computing devices networked together to provide greater processing capability. The system bus 110 can be any of several types of bus structures including a memory bus or memory controller, a peripheral bus, and a local bus using any of a variety of bus architectures. A basic input/output (BIOS), containing the basic routine that helps to transfer information between elements within the computing device 100, such as during start-up, is typically stored in ROM 140. The computing device 100 further includes storage means such as a hard disk drive 160, a magnetic disk drive, an optical disk drive, tape drive or the like. The storage device 160 is connected to the system bus 110 by a drive interface. The drives and the associated computer readable media provide nonvolatile storage of computer readable instructions, data structures, program modules and other data for the computing device 100. The basic components are known to those of skill in the art and appropriate variations are contemplated depending on the type of device, such as whether the device is a small, handheld computing device, a desktop computer, or a computer server.

Although the exemplary environment described herein employs the hard disk, it should be appreciated by those skilled in the art that other types of computer readable media which can store data that are accessible by a computer, such as magnetic cassettes, flash memory cards, digital versatile disks, cartridges, random access memories (RAMs), read only memory (ROM), a cable or wireless signal containing a bit stream and the like, can also be used in the exemplary operating environment.

To enable user interaction with the computing device 100, an input device 190 represents any number of input mechanisms, such as a microphone for speech, a touch-sensitive screen for gesture or graphical input, keyboard, mouse, motion input, speech and so forth. The input may be used by the presenter to indicate the beginning of a speech search query. The device output 170 can also be one or more of a number of output means. In some instances, multimodal systems enable a user to provide multiple types of input to communicate with the computing device 100. The communications interface 180 generally governs and manages the user input and system output. There is no restriction on the invention operating on any particular hardware arrangement and therefore the basic features here may easily be substituted for improved hardware or firmware arrangements as they are developed.

FIG. 2 represents a MPLS network of the present application. In this non-limiting illustration there are six routers in the network, two Label Edge Routers (LER) 210 and 260 and four Label Switched Routers (LSR) 220, 230, 240, and 250, all six are connected to the protocol monitor 270. Prior to packets being sent through the MPLS network 200 the LER 210 communicates with LSRs 220 and 230 using the Label Distribution Protocol (LDP). Labels are sent forward from LER 210 through LSRs 220 and 230 to LER 260. The path that the label follows from LER 210 to LER 260 is called the Label Switched Path (LSP). If both LSRs 220 and 230 are communicating properly through the LDP with LERs 210 and 260 then the packets will follow that LSP. However, if the LDP encounters any problems in either of the LSRs 220 or 230 in trying to communicate with LER 260 then the LDP will choose a different path to get to LER 260. In FIG. 2 the alternate path is through LSRs 240 and 250. However, when the LDP fails to establish a LSP through a node, this information is used by the network to choose a different path. As the network chooses a different path that bypasses a particular node, those transactions are collected by the monitor 270.

The monitor 270 is able to monitor the transactions within the LDP and evaluate each transaction for indications of degradation in the network. The LDP transactions can be discovery messages, session messages, advertisement messages, notification messages, or any other known transaction to those having ordinary skill in the art. There are many causes for the LDP to encounter a failure; a non-comprehensive list includes massive failures, timeouts, hardware failures, software failures, communication line failures, an overloaded component, any degradation in the network, or any failures that are of knowledge to those of ordinary skill in the art. Each time the monitor 270 detects the signature of degradation within the network, it will actively monitor the source of that signature. The monitor determines if further attention is required by comparing that signature of degradation to an allowable threshold value.

This threshold value can take the form of monitoring the paths that packets take to see if a node is avoided continuously over certain period of time. A further threshold is determined by the monitor 270 checking the node hardware via a transmitted signal to see if it is functioning at an acceptable level. The monitor can also keep track of transfer rates within the network and alerting the fault management system if a particular node continuously rejects large transfers. There are many further metrics usable for threshold determination that are apparent to those having ordinary skill in the art, and are well within the scope of the present claims. This threshold value can also determine if it is a temporary problem, such as a temporary spike in activity that caused the LDP to choose a different LSP, or if it is a chronic problem, like hardware failure, in need of further inspection.

The monitor 270 can passively monitor all transactions that take place between each router, both LERs and LSRs, in order to detect any shortcoming in the system. When degradation in the system reaches a threshold value, then the monitor 270 will notify the fault management system 280 that it should log the degradation in the system. After this logging takes place, the fault management system 280 will notify the ticketing system 290, and the ticketing system will produce a notification that the specific problem needs to be addressed. Degradation in the system of any form will be considered a failure for the purposes of the present system. Once the failures or degradations affect the operation of the network in a significant way such that the threshold acceptability of those failures is eclipsed, then the fault management system 280 is notified.

In a further embodiment of the system the fault management system 280 is able to take the notification from the monitor and discern the type and cause of the degradation in the network. If the error is of a type that can be fixed automatically, the fault management system will send a control signal to the appropriate node with instructions that should solve the problem. These instructions can be a reset signal, a signal to switch to backup hardware, or a patch for software, just to name a few. Upon confirmation that the control signal was received, the monitor 270 will actively monitor the node in question and transmit the results of the attempted fix to the fault management system 280. If the problem is solved, the fault management system 280 will log the rendered service and produce the subsequent notification to the ticketing module. If the problem has not been solved, the fault management system 280 will either attempt any other appropriate solutions, notify the ticketing module of the problem, or both. The fault management system 280 can be configured to transmit appropriate control signals under specific circumstances and these circumstances are not limited to the example set forth above.

The ticketing system is any system capable of producing a notification to the user that will convey the faults as recognized by the monitor 270 and the fault management system 280. This notification allows the user to apply preventative maintenance or take other measure to reduce the down time experienced by the network.

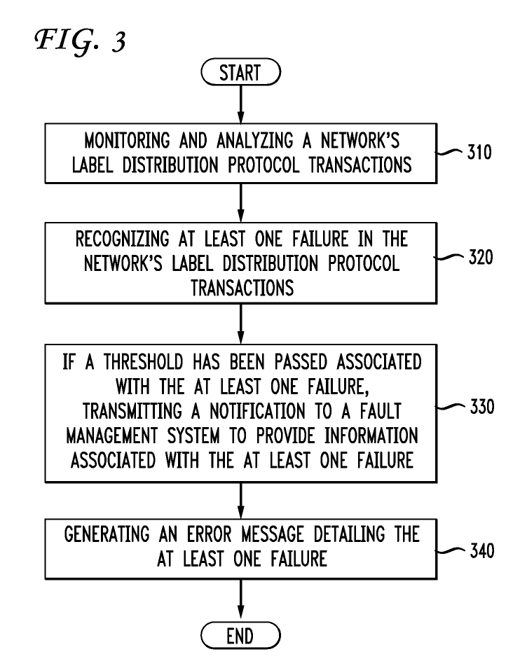

FIG. 3 represents a further embodiment of the present system a method form. As shown, a method of managing fault in a multi protocol label switching system can include: monitoring and analyzing a network's label distribution protocol transactions 310; recognizing at least one failure in the network's label distribution protocol transactions 320; if a threshold has been passed associated with the at least one failure, transmitting a notification to a fault management system to provide information associated with the at least one failure 330; and generating an error message detailing the at least one failure 340.

Embodiments within the scope of the present invention can also include computer-readable media for carrying or having computer-executable instructions or data structures stored thereon. Such computer-readable media can be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium which can be used to carry or store desired program code means in the form of computer-executable instructions or data structures. When information is transferred or provided over a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable media.

Computer-executable instructions include, for example, instructions and data which cause a general purpose computer, special purpose computer, or special purpose processing device to perform a certain function or group of functions. Computer-executable instructions also include program modules that are executed by computers in stand-alone or network environments. Generally, program modules include routines, programs, objects, components, and data structures, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Those of skill in the art will appreciate that other embodiments of the invention can be practiced in network computing environments with many types of computer system configurations, including personal computers, hand-held devices, multi-processor systems, microprocessor-based or programmable consumer electronics, network PCs, minicomputers, mainframe computers, and the like. Embodiments can also be practiced in distributed computing environments where tasks are performed by local and remote processing devices that are linked (either by hardwired links, wireless links, or by a combination thereof) through a communications network. In a distributed computing environment, program modules can be located in both local and remote memory storage devices.

Although the above description may contain specific details, they should not be construed as limiting the claims in any way. Other configurations of the described embodiments of the invention are part of the scope of this invention. For example, the fault management system might be combined with the monitoring system all in one module to facilitate the functioning of the system, however, differences of this sort are well within the scope the claims presently presented. Further examples of further configurations include, multiple monitors to cover a large network or multiple display stations. The claims are not limited to the singular usage of words in the above specification. Accordingly, the appended claims and their legal equivalents should only define the invention, rather than any specific examples given.

I claim:

1. A method of detecting and managing fault within a network, the method comprising:
monitoring and analyzing a network's label distribution protocol transactions;
recognizing at least one failure in the network's label distribution protocol transactions;
if a threshold has been passed associated with the at least one failure, transmitting a notification to a fault management system to provide information associated with the at least one failure; and
generating an error message detailing the at least one failure.

2. The method of claim 1 wherein the network is a MPLS network.

3. The method of claim 1 further comprising:
notifying the fault management system;
if the fault management system determines it can remedy the at least one failure, transmitting a control signal to a node experiencing the at lest one failure;
monitoring the label distribution protocol transactions associated with the node; and
determining if the control signal has remedied the at least one failure.

4. A system for detecting fault in a network, the system comprising:
a module configured to monitor and analyze a network's label distribution protocol transactions;
a module configured to recognize at least one failure in the network's label distribution protocol transactions;
if a threshold has been passed associated with the at least one failure, a module configured to transmit a notification to a fault management system to provide information associated with the at least one failure; and
a module configured to generate an error message detailing the at least one failure.

5. The system of claim 4 wherein the network is a MPLS network.

6. The system of claim 4 further comprising:
a module configured to notify the fault management system;
if the fault management system determines it can remedy the at least one failure, a module configured to transmit a control signal to a node experiencing the at lest one failure;
a module configured to monitor the label distribution protocol transactions associated with the node; and
a module configured to determine if the control signal has remedied the at least one failure.

7. A computer readable medium storing instructions for a computing device to function as a network fault detection system, the instructions comprising:
monitoring and analyzing a network's label distribution protocol transactions;
recognizing at least one failure in the network's label distribution protocol transactions;
if a threshold has been passed associated with the at least one failure, transmitting a notification to a fault management system to provide information associated with the at least one failure; and
generating an error message detailing the at least one failure.

8. The instructions of claim 7 wherein the network is a MPLS network.

9. The instructions of claim 7 further comprising:
notifying the fault management system;
if the fault management system determines it can remedy the at least one failure, transmitting a control signal to a node experiencing the at lest one failure;
monitoring the label distribution protocol transactions associated with the node; and
determining if the control signal has remedied the at least one failure.
